(19) United States
(12) Patent Application Publication
(10) Pub. No.: US 2025/0385493 A1
(43) Pub. Date: Dec. 18, 2025

(54) SELF-ACTUATING LATCH FOR TELECOMMUNICATIONS, FIBER OPTIC, TELEPHONE, ELECTRIC AND CABLE ENCLOSURES, AND PEDESTALS

(71) Applicant: Advanced Pedestals,Inc., Gainesville, TX (US)

(72) Inventors: Eric L Coulston, Justin, TX (US); Jeremy D Williams, Gainesville, TX (US)

(21) Appl. No.: 19/209,495

(22) Filed: May 15, 2025

Related U.S. Application Data
(60) Provisional application No. 63/647,780, filed on May 15, 2024.

(51) Int. Cl. H02B 1/50; H05K 5/02

(52) U.S. Cl. CPC H02B 1/50; H05K 5/0221

(57) ABSTRACT

A self-actuating locking system for a pedestal, including a pedestal base with an internal framework and a pedestal top releasably mounted on the pedestal base. A latch assembly is mounted on an interior face of sidewall pedestal top. A striker bolt assembly is mounted on the pedestal base framework and is captured in the latch assembly when the pedestal top is in its locked-down position.

### CROSS-REFERENCE TO RELATED APPLICATION

This application claims priority in U.S. Provisional Patent Application No. 63/647,780, filed May 15, 2024, which is incorporated herein by reference.

### BACKGROUND OF THE INVENTION

### 1. Field of the Invention

The present invention relates generally to pedestals for telecommunications, fiber optic, telephone, electrical and cable applications, and in particular to a self-actuating, composite latch system for such pedestals.

### 2. Description of the Related Art

Pedestals are commonly used in telecommunications, fiber-optic, telephone, electric and cable applications for protecting connections, junctions, terminals and components from the elements. Transmission line malfunctions can be disruptive and expensive due to network downtime and repairs. Moreover, such malfunctions can occur at remote locations in trans-continental networks, further compromising reliability.

Service providers prioritize the speed, reliability, security, signal clarity and other performance characteristics of their networks. Hence, the network components, including pedestals, are engineered to achieve such customer objectives.

Other design criteria include use of non-corrosive materials. Adaptability to accommodate customer latch type (e.g., hex, star, etc.) criteria and specifications is another objective.

Heretofore there has not been available an enclosure and pedestal latch system with the advantages and features of the present invention.

### BRIEF SUMMARY OF THE INVENTION

The present invention generally provides a composite latch, which is self-actuating for expediting assembly and pedestal closure. The latch assembly generally comprises a box housing utilizing a pivoting, spring-loaded hook latch and corresponding striker.

### BRIEF DESCRIPTION OF THE DRAWINGS

The drawings constitute a part of this specification and include exemplary embodiments of the present invention illustrating various objects and features thereof.

FIG. 1 is a perspective view of a pedestal application of the self-actuating latch system comprising the present invention.

FIG. 2 is a perspective view of the pedestal equipped with a self-actuating latch system of the present invention.

FIG. 3 is a perspective view of the pedestal with an upper portion removed, showing an internal frame mounting a striker bolt assembly.

FIG. 4 is an enlarged, perspective view of the striker bolt assembly mounted on the frame.

FIG. 5 shows an assembled latch assembly of the self-actuating latch system.

FIG. 6 shows the self-actuating latch and striker bolt assemblies.

FIG. 7 is an exploded, perspective of the latch and the striker bolt assemblies of the self-actuating latch system.

FIG. 8 shows a first side of a latch assembly enclosure.

FIG. 9 shows additional views of the first side of the latch assembly enclosure.

FIG. 10 shows more additional views of the first side of the latch assembly enclosure.

FIG. 11 shows section, elevation, plan and perspective views of a second side of the latch assembly enclosure.

FIG. 12 shows additional views of the second side of the latch assembly enclosure.

FIG. 13 shows more additional views of the second side of the latch assembly enclosure.

FIG. 14 shows front, back, right side and perspective views of a latch of the latch assembly.

FIG. 15 shows front, side, back, section and perspective views of a bracket of the striker bolt assembly.

FIG. 16 is a view of the latch assembly in a closed configuration, showing the latch retaining the striker bolt.

FIG. 17 is a view of the latch assembly in an open configuration, showing the latch receiving the striker bolt.

### DETAILED DESCRIPTION OF THE PREFERRED EMBODIMENTS

### I. Introduction and Environment

As required, detailed aspects of the present invention are disclosed herein, however, it is to be understood that the disclosed aspects are merely exemplary of the invention, which may be embodied in various forms. Therefore, specific structural and functional details disclosed herein are not to be interpreted as limiting, but merely as a basis for the claims and as a representative basis for teaching one skilled in the art how to variously employ the present invention in virtually any appropriately detailed structure.

Certain terminology will be used in the following description for convenience in reference only and will not be limiting. For example, up, down, front, back, right and left refer to the invention as orientated in the view being referred to. The words, “inwardly” and “outwardly” refer to directions toward and away from, respectively, the geometric center of the aspect being described and designated parts thereof. Said terminology will include the words specifically mentioned, derivatives thereof and words of similar meaning.

### II. Preferred Embodiment

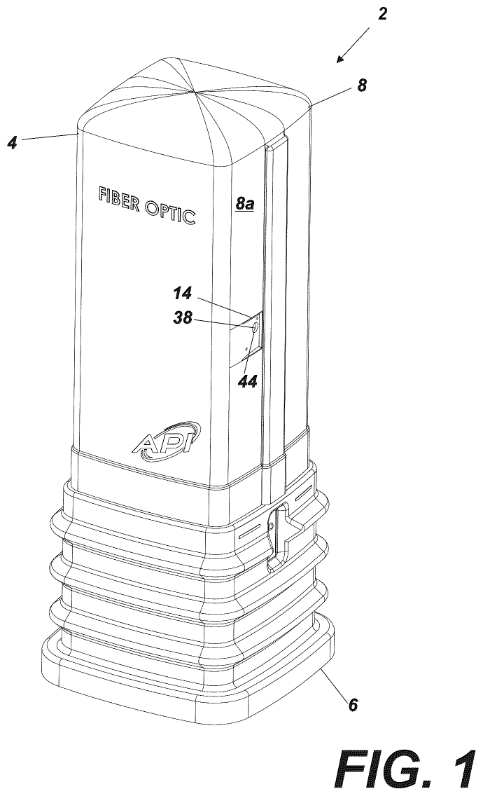

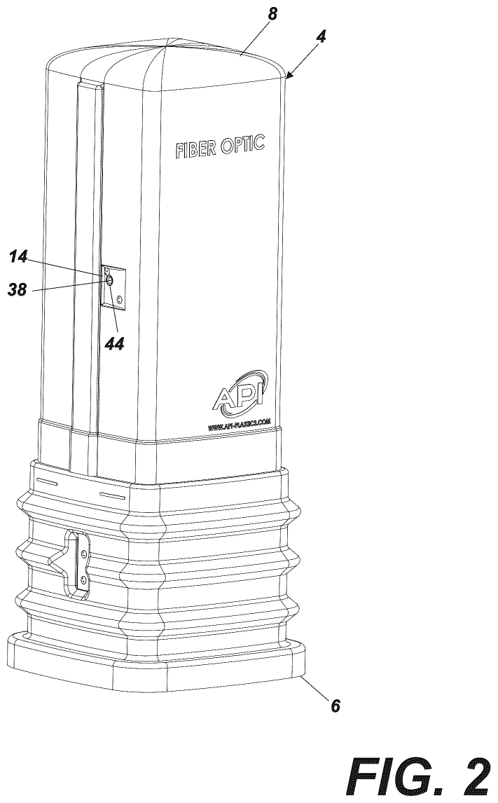

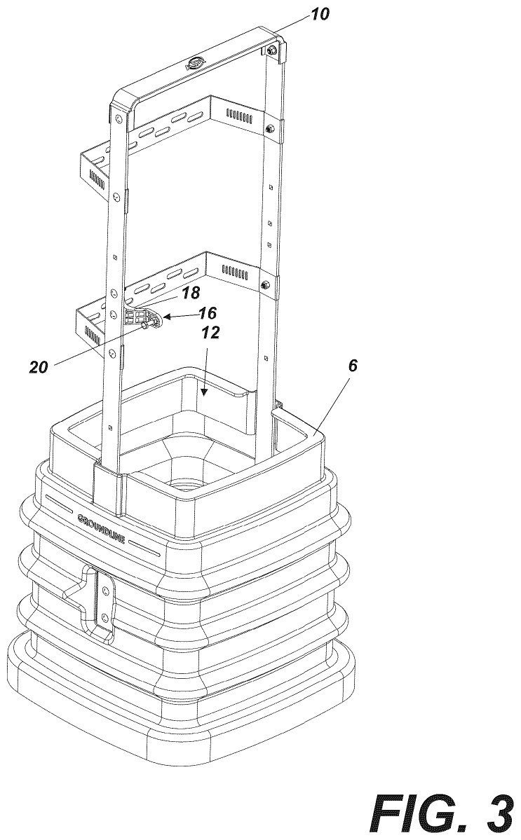

In the practice of the present invention, a self-actuating latch system 2 is provided for a pedestal 4, as shown in FIGS. 1-3. Without limitation on the generality of useful applications for the self-actuating latch system 2, the pedestal 4, as shown, is similar to pedestals commonly used to enclose connections, junctions and other components in electrical networks for telecommunications, fiber-optic cables, power lines, etc. Such pedestals protect the enclosed electrical and fiber-optic components from the elements and provide security. For security purposes, they are commonly locked to limit access to authorized service personnel.

The pedestal 4 generally includes a base 6 configured for anchoring on a ground surface and a removable top 8. An internal framework 10 extends upwardly from the base 6 and releasably attaches the top 8 to form an enclosed pedestal interior 12.

The latch system 2 generally comprises a releasable latch assembly 14 mounted within the pedestal top 8 and a striker bolt assembly 16 mounted on the pedestal framework 10.

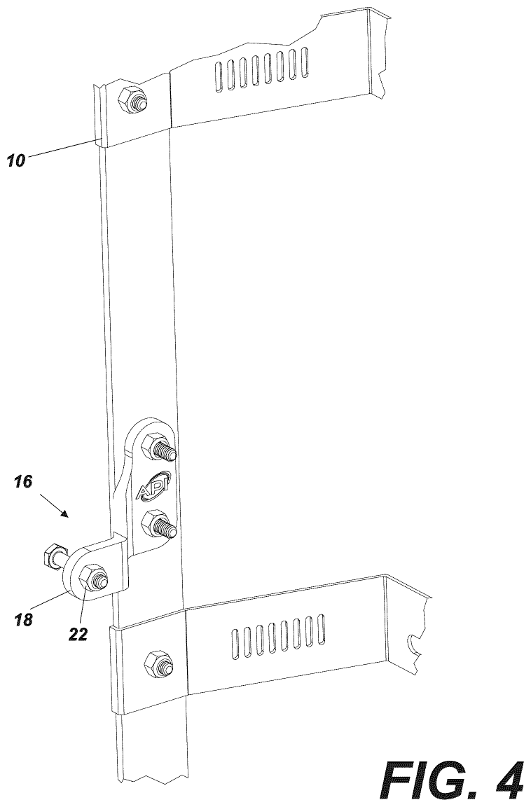

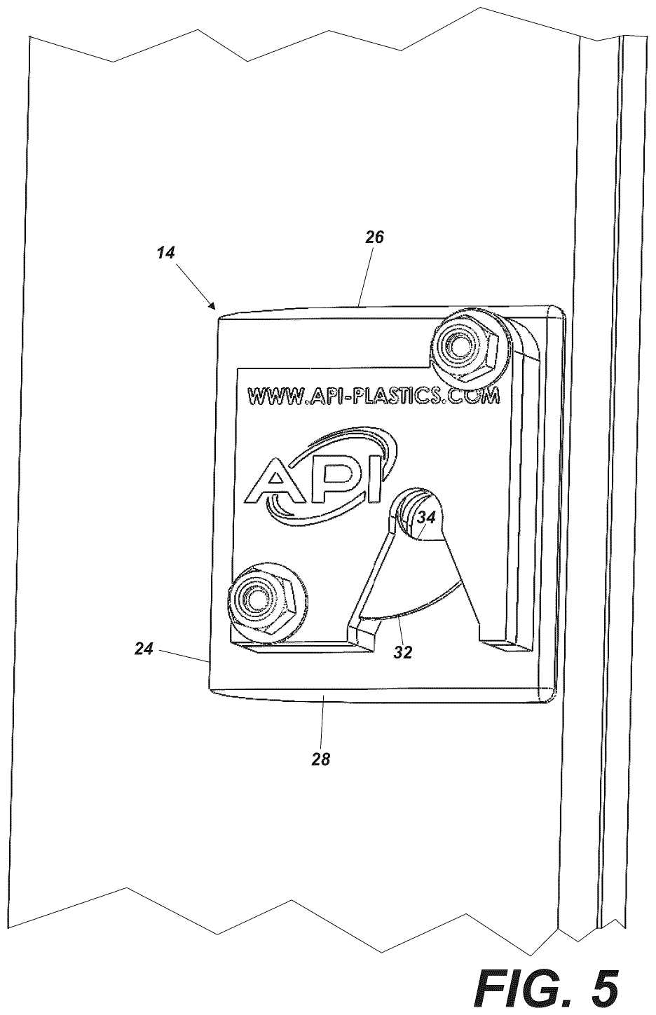

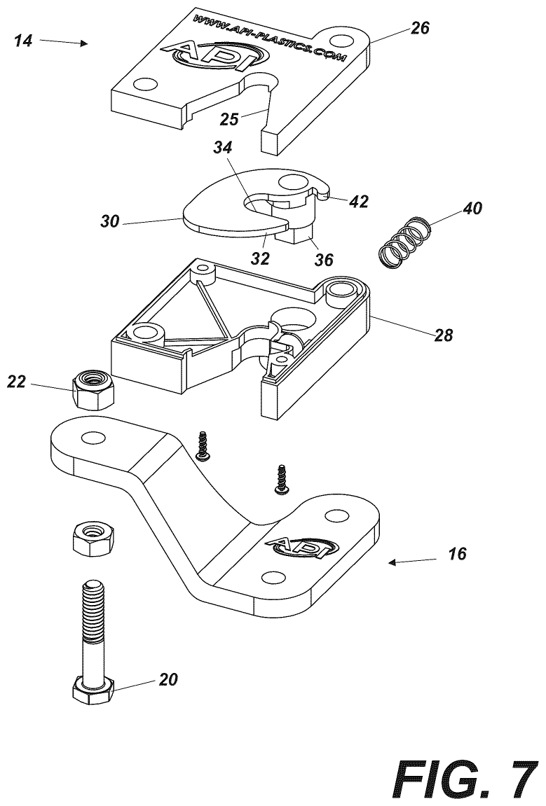

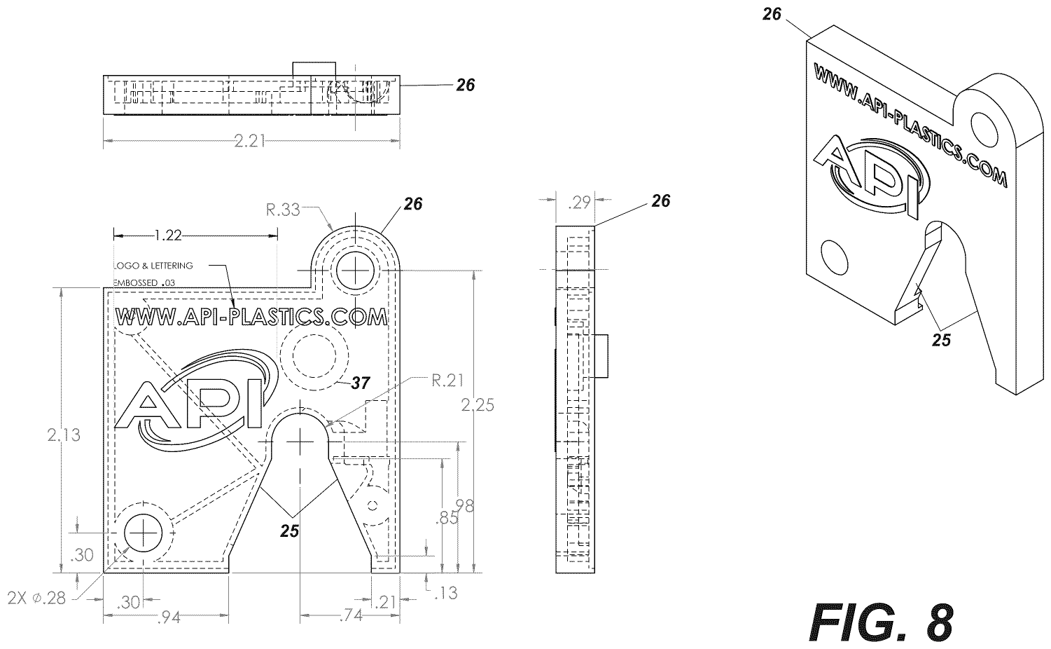

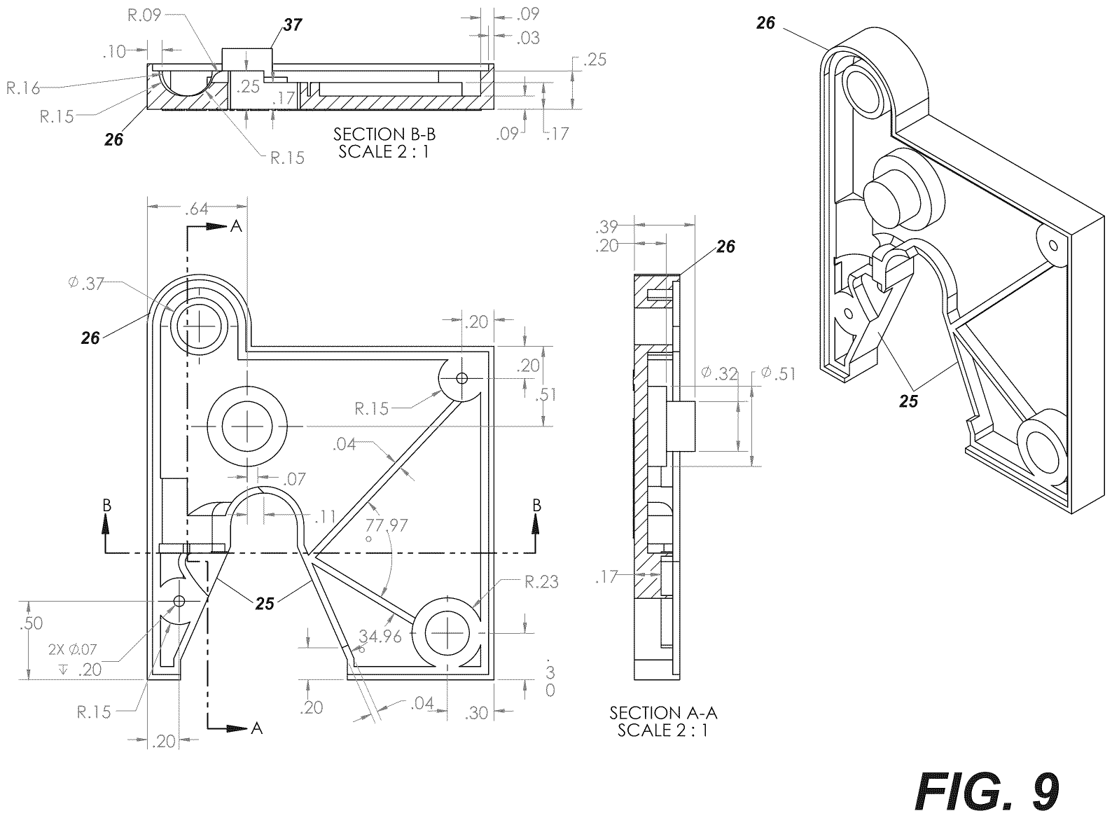

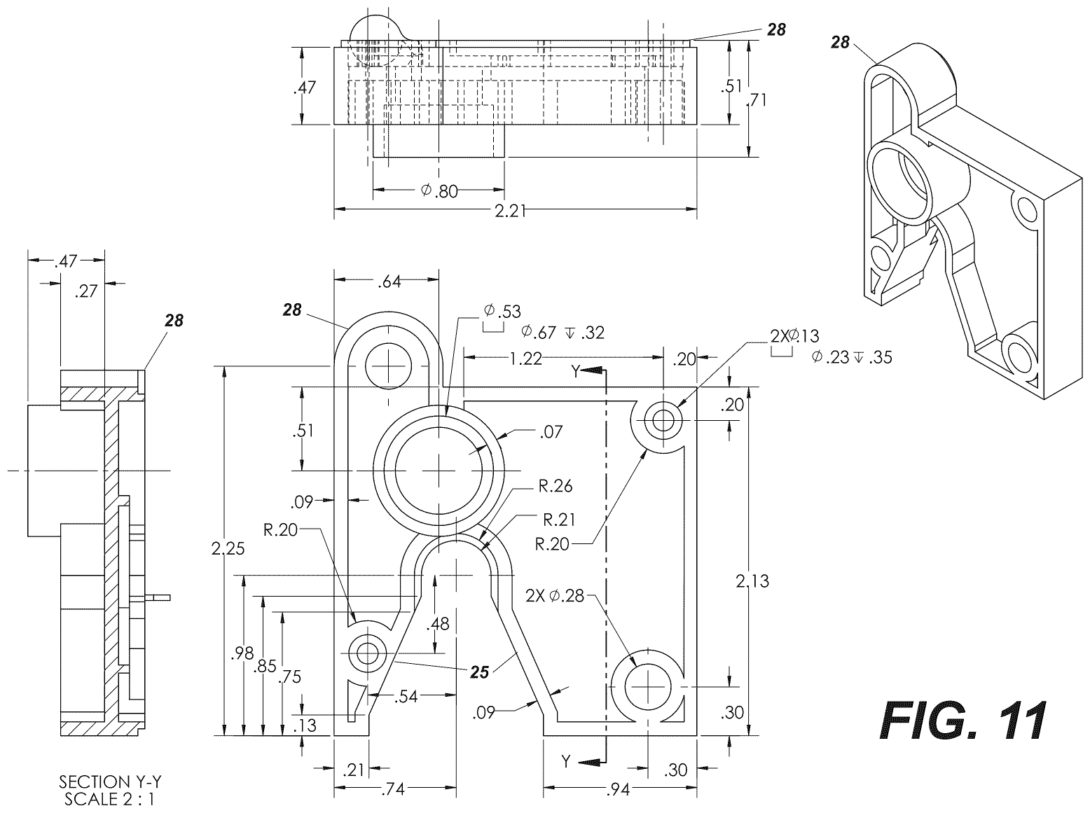

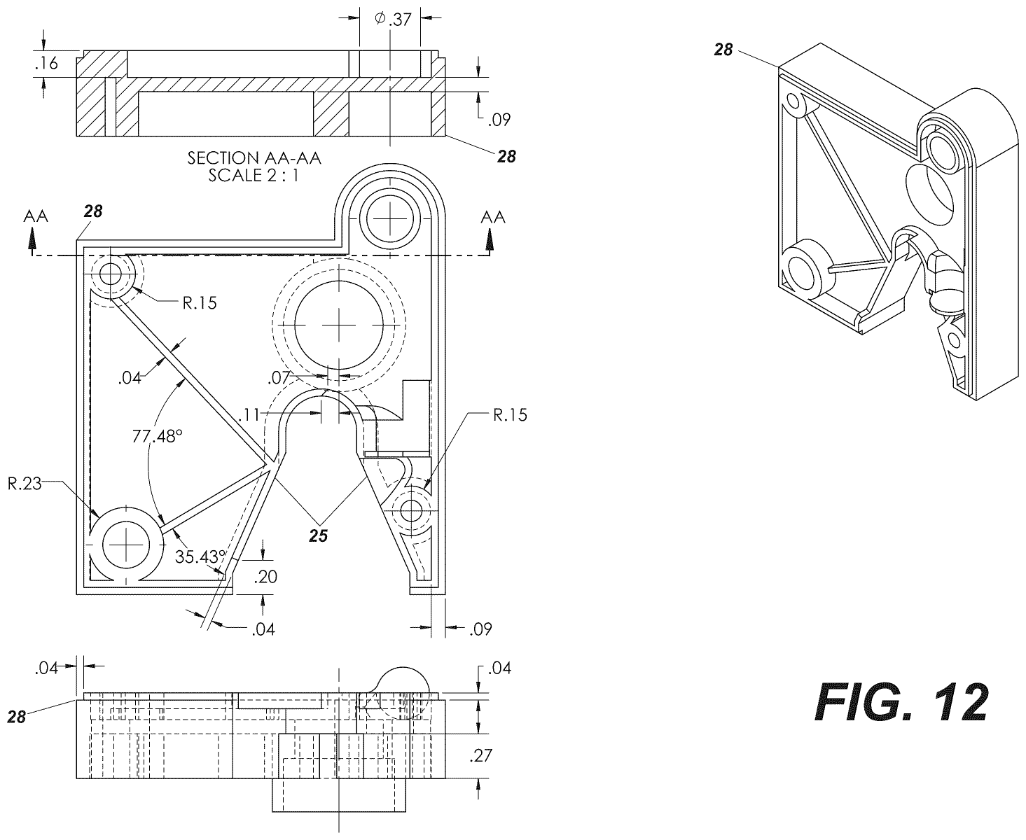

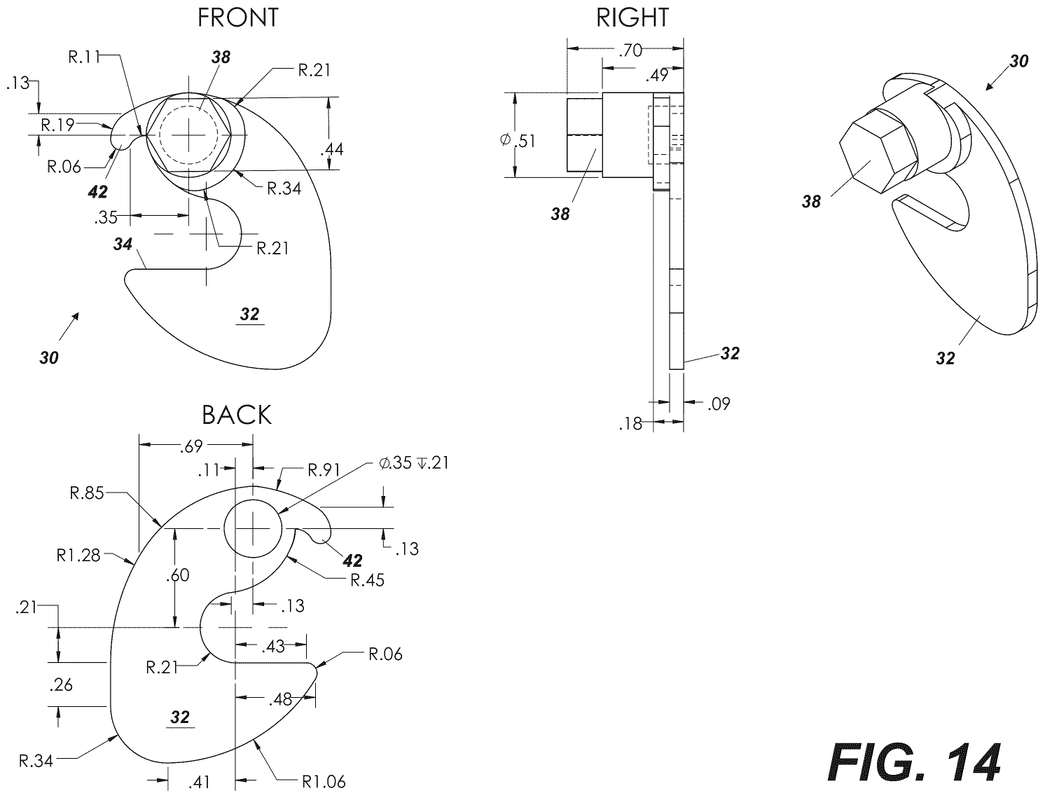

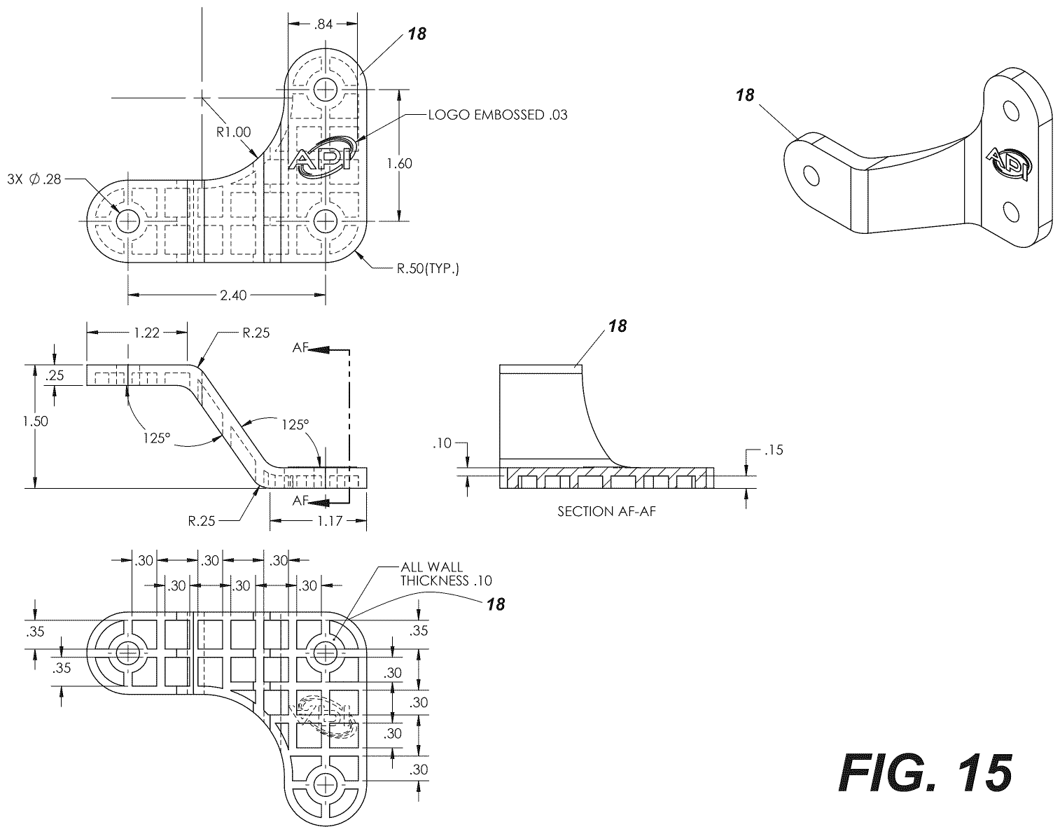

FIGS. 4-17 show the construction and operation of the latch system 2 components. As shown in FIG. 4, the striker bolt assembly 16 includes a bracket 18 bolted to the framework 10 and mounting a striker bolt 20, which is retained in place by a lock nut 22 and extends generally horizontally in proximity to a respective side panel 8a of the pedestal top 8. As shown in FIG. 5, the latch assembly 14 generally includes a latch assembly housing 24 with first and second sides 26, 28 and a latch hook 30 mounted in the latch assembly housing 24. The latch hook 30 is pivotal between a closed position (FIG. 5) for capturing the striker bolt 20 and an open position (FIG. 17) releasing the striker bolt 20.

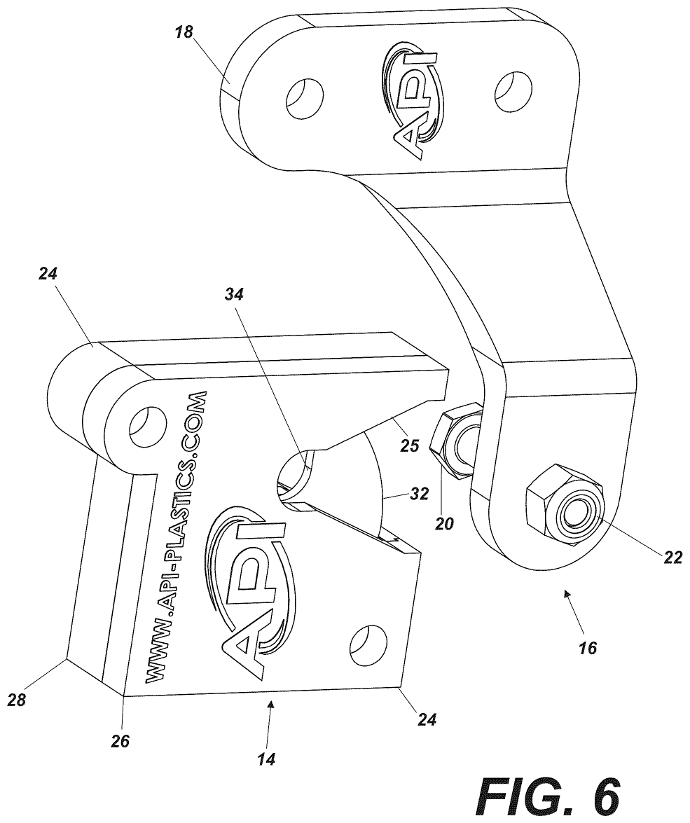

FIG. 6 shows the latch and striker bolt assemblies 14, 16 in closely-spaced, aligned position whereby a slight downward movement of the pedestal top 8 would insert the striker bolt 20 into the latch assembly 14 for securely retaining the pedestal top 8 on the pedestal base 6. The latch assembly housing 24 includes a tapered-wall notch 25, which guides the striker bolt 20 into its locked, retained position.

FIG. 7 is an exploded view of the latch and striker bolt assemblies 14, 16, showing the relationships of their respective components for assembly. The latch hook 30 includes a hook extension 32 partially enclosing a latch hook receiver 34 configured for receiving and retaining the striker bolt 20. A latch hook turning knob 36 extends from the hook extension 32 and terminates at a turning knob hex head 38, which is configured for engagement by a wrench or socket for actuating and releasing the latch system 2. The latch hook turning knob 36 is rotatably mounted on a turning knob boss 37 (FIG. 10).

A latch return helical compression spring 40 is contained within the latch assembly housing 24. The latch hook 30 includes a tab 42, which is inserted into an end of the compression spring 40 for retaining same.

### III. Operation

In operation, the pedestal 4 is assembled by placing the pedestal top 8 over the base 6 and the framework 10 whereby the self-actuating latch assembly 14 and the striker bolt assembly 16 align. When the pedestal top 8 lowers to its final, enclosed position, the latch hook 30 rotates against the latch return compression spring 40, which compresses and then snaps back to capture the striker bolt 20 with the latch hook extension 32.

For access to the pedestal interior 12, e.g., on a service call, the turning knob 36 is rotated to release the latch hook 30 from the striker bolt 20. This can be accomplished by inserting a can wrench (not shown) through an opening 44 in the pedestal top side panel wall 8a and twisting the can wrench. For example, and without limitation, a suitable can wrench is available from Jonard Tools (https://jonard.com/sk-51632-security-key-insert-hex-security-screw-516-532?v=490). Other tools, such as socket wrenches and nut drivers, can also be utilized.

The latch system components are preferably fabricated from weatherproof materials, such as stainless steel and plastics. With the pedestal or other enclosure secured and the latch assembly engaged, internal components are protected from the elements. Weather-related network service interruptions can thus be minimized or avoided altogether.

Moreover, the latch system or assembly enables convenient access to the pedestal internal components for servicing, replacement, etc. Service interruptions during such procedures can thus be minimized.

### IV. Conclusion

The latch system can be adapted for enclosures and housings for various applications. For example, fiber-optic and hardwire connections can be enclosed and shielded from the elements. Telecommunications and media, such as cable networks, can be accommodated. The latch system of the present invention is scalable for installation in pedestals and enclosures of various sizes and shapes.

It is to be understood that while certain embodiments and/or aspects of the invention have been shown and described, the invention is not limited thereto and encompasses various other embodiments and aspects.

1. A self-actuating locking system for a pedestal, including a base with an internal framework and a top with a sidewall having exterior and interior faces, said top releasably mounted on the base framework, which locking system includes:
a latch assembly mounted on the interior face of the side wall of the pedestal top;
said latch assembly including a housing attached to the pedestal top sidewall interior face and a latch hook mounted in said housing;
said latch hook including a hook extension forming a striker bolt receiver and a turning knob extending from said hook extension;
a striker bolt assembly mounted on said pedestal framework including a striker bolt extending generally adjacent said pedestal top sidewall interior face; and
said top having a mounted position on said pedestal base, said striker bolt received in said latch assembly and a separated position and spaced relation from said pedestal base, said striker bolt released from said latch assembly.
